(19) United States
(12) Patent Application Publication
(10) Pub. No.: US 2005/0166955 A1
(43) Pub. Date: Aug. 4, 2005

(54) Support system for photovoltaic device and method for its use

(76) Inventors: Prem Nath, Rochester Hills, MI (US); Subhendu Guha, Bloomfield Hills, MI (US)

Correspondence Address: Ronald W. Citkowski;Gifford, Krass, Groh, Sprinkle,, Anderson & Citkowski, P.C., 280 N. Old Woodward Ave., Suite 400, Birmingham, MI, 48009, US

(21) Appl. No.: 11/006,959

(22) Filed: Dec. 8, 2004

Related U.S. Application Data
(60) Provisional application No. 60/540,166, filed on Jan. 29, 2004.

(51) Int. Cl. H01L 25/00

(52) U.S. Cl. 136/251; 52/173.3

(57) ABSTRACT

A support system for retaining a photovoltaic device on a generally planar surface, without any mechanical connection to the surface, includes a frame assembly which rests upon the surface and supports one or more photovoltaic devices in a spaced apart relationship with the surface. At least one ballast pan is attached to the frame assembly. The ballast pan is configured to retain a ballast material therein. The ballast pan may comprise a peripheral ballast pan which extends along the perimeter of the assembly or it may comprise an internal ballast pan which is disposed beneath the photovoltaic device. Also disclosed herein is a method for using the support system.

### RELATED APPLICATION

This application claims priority of U.S. Provisional Patent Application Ser. No. 60/540,166 filed Jan. 29, 2004, and entitled “Support System for Photovoltaic Device and Method for Its Use” which is incorporated herein by reference.

### FIELD OF THE INVENTION

This invention relates generally to photovoltaic power systems. More specifically, the invention relates to support systems for retaining photovoltaic devices on planar surfaces such as flat roofs, paved surfaces and the like, which system does not require penetration of, or mechanical affixation to, the planar surface.

### BACKGROUND OF THE INVENTION

Photovoltaic devices must, of necessity, be exposed to illumination in order to generate electrical current. Moderate to large scale photovoltaic power generating systems frequently occupy areas ranging from tens to thousands of square meters. In many instances, photovoltaic installations are placed on flat roof structures, or other large relatively planar surfaces such as paved areas or the ground, depending upon the nature of the application.

Large planar bodies such as photovoltaic panels are subject to wind loading, and this problem is particularly severe when they are disposed in elevated locations such as on rooftops. Photovoltaic installations can be mechanically affixed to a roof by nails, screws, brackets or other such devices; however, any such roof penetrating hardware can compromise the integrity of the roof and will generally void any manufacturer's warranties. Also, use of mechanical affixation hardware complicates the installation of the devices. Furthermore, if it is necessary to remove the devices for repair, or in instances where the installation is employed as a temporary source of power, such affixation hardware complicates the removal process.

Thus, it will be seen that there is a need for a system and method for supporting photovoltaic devices on a relatively flat surface such as a rooftop, pavement or the like. The system should be simple to install and remove and should not require use of any hardware which penetrates the surface upon which the installation is made. Furthermore, the system must be capable of resisting wind loads.

The prior art has implemented various systems for installing photovoltaic devices onto roofing structures; however, such prior art systems either require mechanical affixation to a roof and/or utilize relatively complex and massive support hardware. Some prior art photovoltaic mounting systems are shown, for example, in U.S. Pat. Nos. 5,746,839; 6,617,507; 6,495,750; 6,501,013; 6,534,703; 6,570,084; 6,606,823 and 4,886,554.

As will be described hereinbelow, the present invention provides a lightweight, easy to install and disassemble system for supporting photovoltaic devices on roofs and other flat surfaces. The system does not require any penetration of an underlying roof structure. While the system is relatively lightweight, it is very resistant to wind loading. These and other advantages of the present invention will be apparent from the drawings, discussion and description which follow.

### BRIEF DESCRIPTION OF THE INVENTION

Disclosed herein is a support system for retaining a photovoltaic device on a generally planar surface such as a roof. The support system includes a frame assembly which comprises a first plurality of rail members which are configured to be disposed upon the surface, and a second plurality of rail members which are joined to the first plurality of rail members in an angled relationship thereto. The second plurality of rails are operative to support a photovoltaic device in a spaced apart relationship with the surface. The support system also includes at least one ballast pan which is attached to the frame assembly and which is configured to retain a ballast material therein. The support system is further characterized in that it is operable to retain the photovoltaic device on the surface without requiring that the support system be mechanically connected to the surface.

In some embodiments, the ballast pan is a skirt-like member which projects from, and extends along, at least a portion of the perimeter of the frame assembly. In other instances, the ballast pan may comprise an internal ballast pan which is joined to at least one member selected from the first plurality of rails and the second plurality of rails. This ballast pan is disposed in the space which is defined between the support surface and the photovoltaic device. Assemblies of the present invention may include various combinations of internal ballast pans and/or skirt-like peripheral ballast pans.

In particular embodiments, the support system further includes an electrical junction box which may be supported on the frame or on one of the ballast pans, or otherwise disposed. In other instances, the support system may include a plurality of vent openings defined therethrough which establish fluid communication between an ambient atmosphere and the space bounded by the photovoltaic device and the surface upon which the support system rests. Among the photovoltaic devices which may be employed in the practice of the present invention are standing seam photovoltaic devices, as well as photovoltaic devices supported on polymeric or ceramic substrates.

Also disclosed herein is a method for retaining a photovoltaic device on a generally planar surface through the use the subject support assembly.

### BRIEF DESCRIPTION OF THE DRAWINGS

FIG. 1 is a perspective view of one photovoltaic power generating installation incorporating the support system of the present invention;

FIG. 2 is a depiction of the frame portion of the assembly of FIG. 1;

FIG. 3 is a depiction of some particular rail members used in the frame assembly of FIG. 2;

FIG. 4 is an illustration of a portion of another embodiment of support assembly of the present invention; and

FIG. 5 is an enlarged view of a portion of the assembly of FIG. 1 showing the electrical junction box thereof.

### DETAILED DESCRIPTION OF THE INVENTION

The present invention comprises a support system for retaining photovoltaic devices on a planar surface such as a flat roof, a paved surface, a body of smooth earth or the like. It is a notable feature of the present invention that the system does not need to be fastened to the underlying substrate, but relies upon gravity and its configuration to resist wind loads which would tend to lift or otherwise displace the relatively lightweight, large area photovoltaic installations. The system includes a lightweight frame which rests upon the support surface. Photovoltaic devices are affixed to the frame by mechanical fasteners, adhesives and the like. Also affixed to the frame is at least one ballast pan. The ballast pan is filled with a ballasting material such as aggregate, concrete blocks, sandbags, or the like and serves to anchor the installation onto the support surface. As will be described hereinbelow, various configurations of frames and ballast pans may be used in the practice of the present invention.

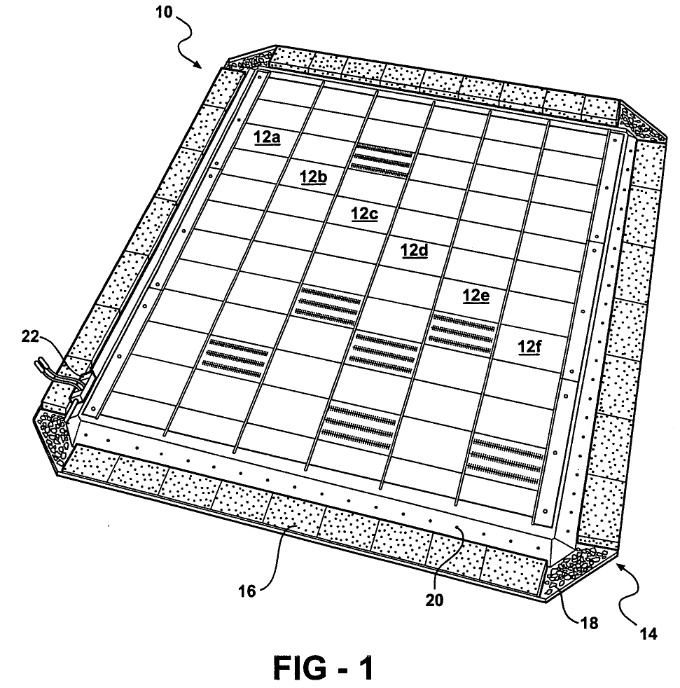

Referring now to FIG. 1, there is shown one particular embodiment of support system 10 used in a photovoltaic installation in accord with the present invention. The installation 10 of FIG. 1 includes photovoltaic panels 12a-12f, which in this embodiment are standing seam photovoltaic panels which are comprised of a thin film photovoltaic device affixed to a relatively rigid metallic support substrate having standing edge seams which are interlockable with adjoining standing seams of like panels. Photovoltaic devices of this type are known in the art and are shown, for example, in U.S. Pat. Nos. 5,968,287; 5,232,518; and 4,040,867, the disclosures of which are incorporated herein by reference. It is to be understood that the present invention may be practiced with photovoltaic panels which are otherwise configured.

In the FIG. 1 embodiment, the photovoltaic panels 12a-12f are supported on a frame member which is not visible in this drawing. As is further shown in FIG. 1, a ballast pan 14 extends around the perimeter of the assembly. This ballast pan 14 is typically fabricated from a relatively durable, lightweight material such as a ferrous or nonferrous sheet metal, a high strength polymer or the like. The ballast pan 14 is configured as a skirt which retains a ballasting material therein, and as is shown herein, a series of cement blocks, for example block 16, are retained in the ballast pan 14. As is also shown in this drawing, the corner portions of the ballast pan 14 have volumes of crushed stone aggregate 18 retained therein.

As is further illustrated, a series of vent holes are formed in the ballast pan, and one such hole is shown at reference numeral 20. While the vent holes are optional, it has been found that, in some instances, inclusion of vent holes allows the air pressure beneath the installation to equilibrate with ambient air pressure so that the tendency of a wind load to lift the installation from the surface on which it is disposed is minimized. As is further shown in FIG. 1, the installation includes an electrical junction box 22 which is supported on the ballast pan 14. The junction box, as will be explained in detail hereinbelow, provides a connection point at which electrical contact to the photovoltaic panels 12a-12f of the installation may be made. It is to be understood that the junction box may be otherwise disposed. For example, the junction box may be disposed beneath the photovoltaic devices. In other instances, the junction box may be eliminated, and connections directly made to each of the photovoltaic devices. Also, even in instances where a junction box is employed, individual connectors may be utilized to establish a series, parallel, or mixed series/parallel connection between the individual photovoltaic devices 12a-12f so as to produce an appropriate power output. Use of such individual connectors also allows for the simple replacement of one of the photovoltaic panels, 12, of the installation.

In the installation of FIG. 1, the combination of the skirt-like ballast pan 14 and the frame combine to retain the installation on a horizontal surface so as to be resistant to wind loading or other disrupting forces. In a typical assembly, the level of ballasting in the pan 14 is approximately 10 pounds per square foot and the overall load imposed on the surface by an assembly of this type is approximately 2.7 pounds per square foot. These loading levels are compatible with most roofing structures and building codes.

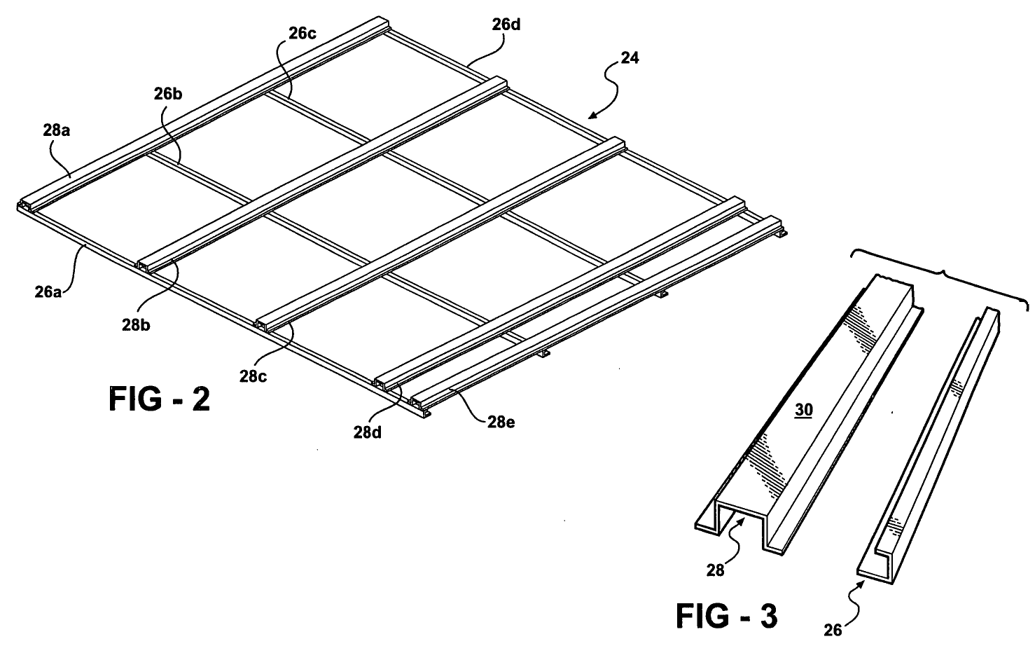

FIG. 2 shows a frame assembly 24 which may be employed in the FIG. 1 installation. This frame assembly 24 is a rigid, relatively lightweight structure comprised of a number of rails fabricated from a high strength lightweight material such as sheet metal or high strength polymers. As is specifically shown, the frame is comprised of a first plurality of rails 26a-26d and a second plurality of rails 28a-28e. It is to be understood that, depending upon the particular application, a larger or smaller number of rails may be employed. The first plurality of rails 26a-26d rest upon the roof or other surface upon which the installation is to be supported. The second plurality of rails 28a-28e are disposed in an angled relationship (in this instance a right angled relationship) with the first plurality of rails, and are mechanically affixed thereto by welds, adhesives, screws, bolts, clamps or other such means. The second group of rails 28a-28e are configured to support one or more photovoltaic devices thereupon. As will be described in detail hereinbelow, the frame 24 is also operable to retain one or more ballast pans affixed thereto.

Referring now to FIG. 3, there is shown a detailed depiction of a first rail 26 and a second rail 28. As will be seen, the first rail 26 has a generally C-shaped cross section and the second rail 28 has a “hat” configuration which provides a relatively large area, flat top surface 30 which facilitates affixation of the photovoltaic devices thereto. The C-shaped cross-section of the first rail 26 facilitates affixation of internal ballast pans, as will be described hereinbelow, to the frame. It is to be understood that the rails may be otherwise configured. For example, both rails may comprise C-shaped or hat-shaped members. Alternatively, one or both rails may comprise a circular or flattened tubular member, or in other instances, various of the rails may comprise solid members.

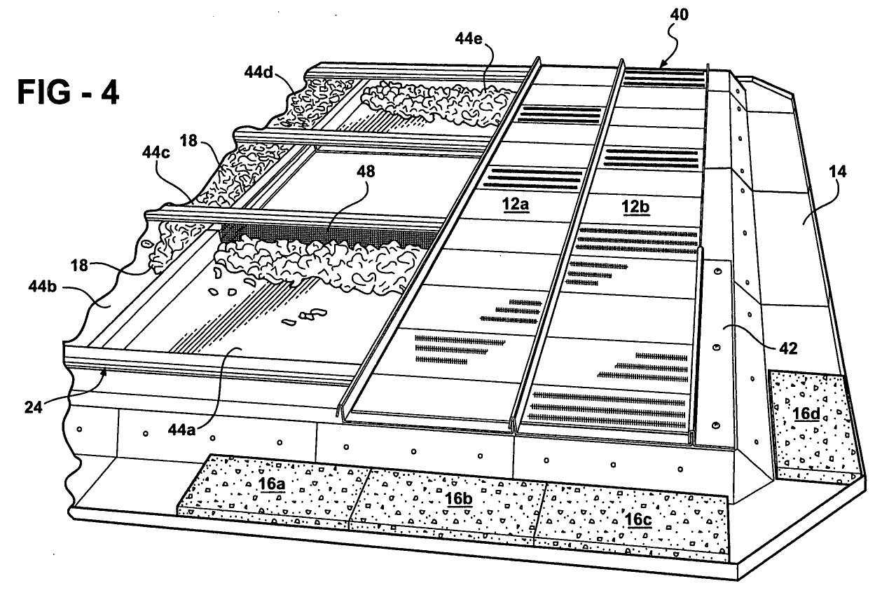

Referring now to FIG. 4, there is shown a partial, cutaway view of another embodiment of photovoltaic installation 40 utilizing the system of the present invention. Visible in FIG. 4 is a frame assembly 24 which is generally similar to that discussed with reference to FIG. 2. Supported on the frame are two photovoltaic generator panels 12a, 12b as generally described above. As in the previous embodiment, a skirt-like ballast pan 14 extends around the perimeter of the system, and a number of cement blocks 16a-16d are disposed in the pan 14. As is further shown in FIG. 4, a cover strip 42 is disposed atop an upper portion of the ballast pan 14. The cover strip 42 engages, and fits over, the seam portion of the photovoltaic device 12b and aids in mechanically coupling the photovoltaic device 12b to the ballast pan 14 and frame 24. In a typical installation, additional cover pieces 42 will be included.

The FIG. 4 embodiment further includes a series of internal ballast pans 44a-44e which are affixed to the frame 24. These pans 44 are, in this embodiment, attachable to the first plurality of rails 26 and serve to hold a ballasting material such as the illustrated crushed stone aggregate 18, although they may likewise hold concrete blocks, sand or other such ballasting material. In the illustrated embodiment, a portion of the frame does not include a ballasting pan and, as will be seen, ballast pan 44a includes a body of screen material 48 which serves to confine the aggregate. It is to be understood that the screen may be dispensed with in some instances, depending upon the nature of the ballasting material and/or its need for containment. In other instances, the ballast may be contained by appropriately configuring the ballast pan 44, such as by turning up an edge. The internal ballast pans may be used as an alternative to the skirt-like peripheral ballast pan, or they may be used in conjunction with a peripheral ballast pan.

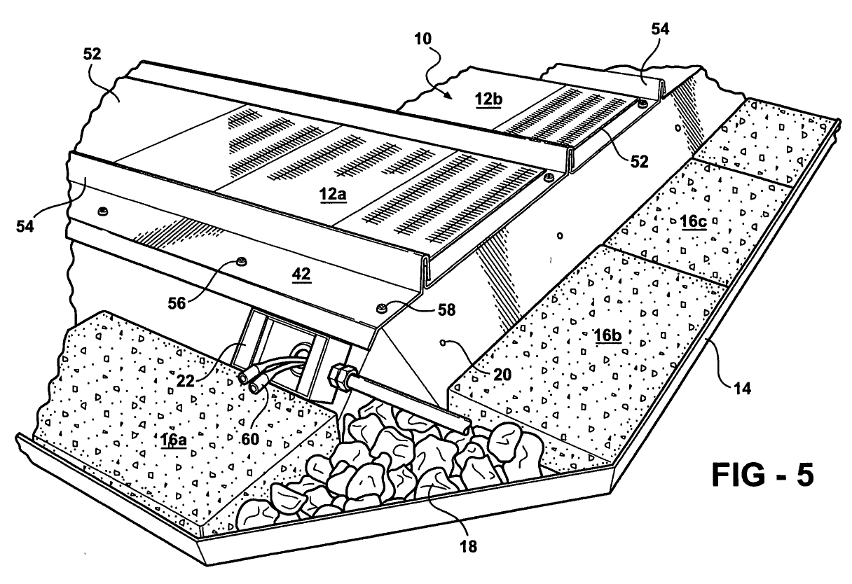

Referring now to FIG. 5, there is shown an enlarged view of a portion of the installation 10 of FIG. 1 better illustrating certain features thereof. As will be seen, the illustration shows photovoltaic devices 12a and 12b, and as will be seen, they generally comprise a body of thin film based photovoltaic material 52 adhesively affixed to a standing seam, metallic substrate 54. As will also be noted, the standing seam portions of adjoining devices 12a, 12b are mechanically interlocked.

In this embodiment, a skirt-like ballast pan 14 extends from the perimeter of the installation and as was previously described includes a number of cement blocks 16a-16c and a body of crushed stone aggregate 18 retained therein. Also as previously described, a series of holes 20 is formed in one of the faces of the ballast pan 14, and these holes 20 serve to equalize pressure outside and beneath the installation so as to minimize the effect of wind loading.

As was described with reference to FIG. 4, a cover strip 42 is affixed to the ballast pan by means such as self-tapping screws 56, 58, and this strip 42 engages the standing seam of device 12a thereby better anchoring it to the ballast pan.

Also, as described with reference to FIG. 1, the installation includes an electrical junction box 22 which is supported on the ballast pan 14. The junction box 22 is shown with its faceplate removed, and as will be seen, it includes a pair of electrical terminals 60, 62 which serve to establish electrical communication with the photovoltaic devices 12a, 12b. The junction box 22 further includes a conduit 64 which can enclose current carrying wires which allow the installation to be interconnected to other sources or loads.

While the foregoing is a description of some particular embodiments of the present invention, it is to be understood that in view of the disclosure presented herein, yet other embodiments will be readily apparent and available to one of skill in the art. As noted above, the system may be implemented utilizing either or both of internal and peripheral ballast pans. Also, while the peripheral ballast pan has been shown in FIG. 1 as extending around the entire perimeter of the installation, peripheral ballast pans may be utilized on only a portion of the perimeter. For example, peripheral ballast pans may be employed on two opposite edges of a rectangular installation. Alternatively, a series of shorter peripheral ballast pans may be spaced along the entire perimeter of an installation. In such instances, the relatively large open areas will allow for pressure equalization as well as ventilation. Also, while the installations have been shown as being generally rectangular, it is to be understood that other installations, including polygonal as well as curved installations, may be employed in accord with the teaching presented herein. Also, while the system has been shown as being implemented in connection with standing seam photovoltaic devices which include thin film photovoltaic materials, installations of this type may be implemented utilizing other photovoltaic materials including single crystalline material as well as materials disposed on non-standing seam substrates such as polymeric based substrates, ceramic substrates and the like. The foregoing drawings, discussion and description are illustrative of particular embodiments of the invention but are not meant to be limitations upon the practice thereof. It is the following claims, including all equivalents, which define the scope of the invention.

1. A support system for retaining a photovoltaic device on a generally planar surface, said support system comprising:
a frame assembly comprising a first plurality of rail members which are configured to be disposed upon said surface, a second plurality of rail members which are joined to said first plurality of members in an angled relationship thereto, said second plurality of rails being disposed and operative to support a photovoltaic device in a spaced-apart relationship with said surface; and
a ballast pan which is attached to said frame assembly and which is configured to retain a ballast material therein; whereby said support system is operable to retain said photovoltaic device on said surface without requiring that said support system be mechanically connected to said surface.

2. The support system of claim 1, wherein said ballast pan projects from, and extends along, at least a portion of the perimeter of the frame assembly.

3. The support system of claim 1, wherein said ballast pan is joined to at least one member selected from said first plurality of rails and said second plurality of rails so that said ballast pan is disposed in a space defined between said support surface and a photovoltaic device which is supported by said second plurality of rails.

4. The support system of claim 1, further including a plurality of vent openings passing therethrough so as to establish fluid communication between an ambient atmosphere and a space bounded by said surface and a photovoltaic device supported by said second plurality of rails.

5. The support system of claim 1, further including an electrical junction box.

6. The support system of claim 5, wherein said electrical junction box is supported upon a ballast pan which projects from, and extends along, at least a portion of the perimeter of the frame assembly.

7. The support system of claim 1, wherein at least one of said first plurality and second plurality of rail members is comprised of members having a C-shaped cross section.

8. The support system of claim 1, wherein at least one of said first plurality of rail members and second plurality of rail members is comprised of members having a hat-shaped cross section.

9. The support system of claim 1 further including a plurality of photovoltaic devices which are supported by said second plurality of rails.

10. The support system of claim 9, wherein each of said photovoltaic devices comprises a standing seam panel having a photovoltaic material affixed thereto.

11. The support system of claim 10, wherein adjacent standing seams of said photovoltaic devices are mechanically interlocked.

12. The support system of claim 10, wherein said photovoltaic material is adhesively affixed to said standing seam panels.

13. The support system of claim 9, wherein said photovoltaic material comprises a flexible, thin film photovoltaic material.

14. A support system for retaining an array of photovoltaic devices on a generally planar surface, said system comprising:
a frame assembly which is configured to rest upon said planar surface and to support a photovoltaic device in a spaced-apart relationship with said surface; and
a ballast pan which is attached to said frame assembly and which is configured to retain a ballast material therein.

15. A method for retaining a photovoltaic device on a generally planar surface, said method comprising the steps of:
providing a support system, said support system including a frame assembly which is configured to rest upon the planar surface and to support a photovoltaic device in a spaced-apart relationship with said surface; and a ballast pan which is attached to said frame assembly and which is configured to retain a ballast material therein;
affixing a photovoltaic device to said frame assembly; and
disposing a ballast material in said ballast pan.

16. The method of claim 15, wherein said frame assembly comprises a first plurality of rail members which are disposed upon said surface, and a second plurality of rail members which are joined to said first plurality of rail members in an angled relationship thereto; and
wherein said step of affixing a photovoltaic device to said frame assembly comprises affixing said photovoltaic device to said second plurality of rail members.

17. The method of claim 15, wherein said ballast pan projects from, and extends along, at least a portion of the perimeter of the frame assembly.

18. The method of claim 15, wherein said ballast pan is joined to said frame so that said ballast pan is disposed in a space defined between said support surface and the photovoltaic device.

19. The method of claim 15, wherein said support system is not mechanically affixed to said planar surface.
